(19) United States
(12) Patent Application Publication
(10) Pub. No.: US 2025/0087526 A1
(43) Pub. Date: Mar. 13, 2025

(54) SEMICONDUCTOR MANUFACTURING APPARATUS

(71) Applicants: Kabushiki Kaisha Toshiba, Tokyo (JP); Toshiba Electronic Devices & Storage Corporation, Tokyo (JP)

(72) Inventor: Shun HASEBE, Nonoichi Ishikawa (JP)

(21) Appl. No.: 18/437,119

(22) Filed: Feb. 8, 2024

(30) Foreign Application Priority Data
Sep. 7, 2023 (JP) 2023-145624

(51) Int. Cl. H01L 21/687; G01R 1/073

(52) U.S. Cl. CPC H01L 21/68785; G01R 1/07307; H01L 21/68728

(57) ABSTRACT

A semiconductor manufacturing apparatus according to the present embodiment includes a stage configured to support a semiconductor wafer. A probe card is positioned above the stage. A first electrode is formed of a conductive material, is movable on the stage from an outer side of the stage toward a center, and is contactable with a side surface of the semiconductor wafer.

### CROSS REFERENCE TO RELATED APPLICATIONS

This application is based upon and claims the benefit of priority from the prior Japanese Patent Application No. 2023-145624, filed on Sep. 7, 2023, the entire contents of which are incorporated herein by reference.

### FIELD

The embodiments of the present invention relate to a semiconductor manufacturing apparatus.

### BACKGROUND

There is a case where a semiconductor manufacturing apparatus is electrically connected to a rear surface of a semiconductor wafer on a stage having the semiconductor wafer placed thereon.

However, when an insulating layer is formed on the rear surface of a semiconductor wafer, the stage cannot be electrically connected to the substrate of the semiconductor wafer. In this case, the electrical characteristics of the semiconductor wafer cannot be measured by the semiconductor manufacturing apparatus.

Meanwhile, if the insulating layer on the rear surface of the semiconductor wafer is removed, a difference between the front surface stress and the rear surface stress of the semiconductor wafer is generated and the semiconductor wafer is distorted. In this case, it becomes difficult to transfer the semiconductor wafer in a semiconductor manufacturing process.

### BRIEF DESCRIPTION OF THE DRAWINGS

FIG. 1 is a diagram illustrating a configuration example of a probing device according to a first embodiment;

FIG. 2 is a flowchart illustrating an operation example of the probing device according to the first embodiment;

FIG. 3 is a sectional view illustrating a configuration example of a semiconductor wafer placed on a stage;

FIG. 4 is a sectional view illustrating a configuration example of the semiconductor wafer placed on the stage;

FIG. 5 is a sectional view illustrating a manufacturing process of a semiconductor device after a testing process of the semiconductor wafer is performed;

FIG. 6 is a sectional view illustrating the manufacturing process of the semiconductor device in continuation from FIG. 5;

FIG. 7 is a sectional view illustrating the manufacturing process of the semiconductor device in continuation from FIG. 6;

FIG. 8 is a sectional view illustrating the manufacturing process of the semiconductor device in continuation from FIG. 7;

FIG. 9 is a sectional view illustrating the manufacturing process of the semiconductor device in continuation from FIG. 8;

FIG. 10 is a plan view illustrating a configuration example of clamp electrodes according to a second embodiment;

FIG. 11 is a plan view illustrating a configuration example of clamp electrodes according to a third embodiment;

FIG. 12 is a sectional view illustrating a configuration example of clamp electrodes according to a fourth embodiment; and

FIG. 13 is a sectional view illustrating a configuration example of clamp electrodes according to a fifth embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor manufacturing apparatus according A to the present embodiment includes a stage configured to support a semiconductor wafer. A probe card is positioned above the stage. A first electrode is formed of a conductive material, is movable on the stage from an outer side of the stage toward a center, and is contactable with a side surface of the semiconductor wafer.

### First Embodiment

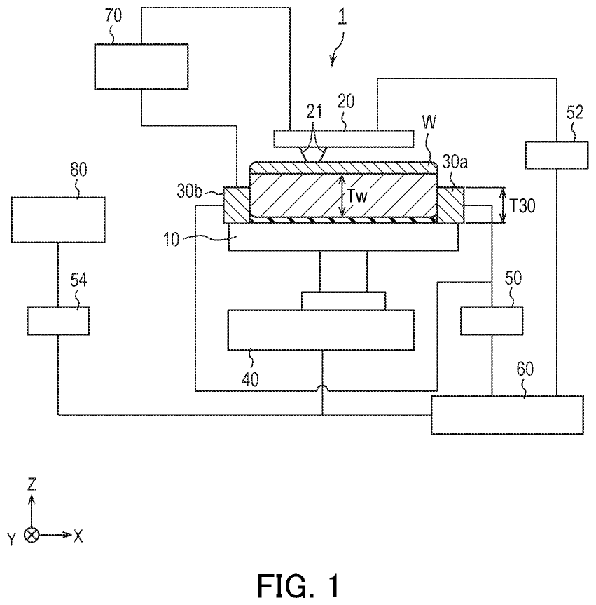

FIG. 1 is a diagram illustrating a configuration example of a probing device according to a first embodiment. A probing device 1 is, for example, a semiconductor manufacturing apparatus such as a semiconductor testing apparatus. The probing device 1 includes a stage 10, a probe card 20, a probe needle 21, clamp electrodes 30a and 30b, a stage driver 40, a clamp driver 50, a probe card driver 52, a transfer arm driver 54, a controller 60, a measuring part 70, and a transfer arm 80.

The stage 10 has a semiconductor wafer W placed thereon and can support the semiconductor wafer W. The stage 10 has a vacuum chuck function or an electrostatic chuck function to absorb a rear surface of the semiconductor wafer W. The semiconductor wafer W has, for example, power semiconductor elements such as an IGBT (Insulated Gate Bipolar Transistor), an HEMT (High Electron Mobility Transistor), a MOSFET (Metal Oxide Semiconductor Field Effect Transistor), or a diode. Therefore, the semiconductor wafer W has a rear electrode as well as a front electrode.

The probe card 20 is positioned above the stage 10 and includes the probe needle 21 that is brought into contact with the front electrode (an electrode pad) of the semiconductor wafer W as a measurement target. The probe card 20 is controlled by the controller 60 and can move in X, Y, and Z directions. After the semiconductor wafer W is placed on the stage 10, the probe card 20 moves to bring the tip of the probe needle 21 into contact with a certain electrode pad of the semiconductor wafer W. It is also possible that the probe card 20 is fixed and that the stage 10 moves in the X, Y, and Z directions. One or both of the stage 10 and the probe card 20 may be movable.

The clamp electrodes 30a and 30b as first and second electrodes are movable on the stage 10 from outer sides of the stage 10 to the center. The clamp electrodes 30 and 30b can approach the semiconductor wafer W from both sides of the semiconductor wafer W and can be brought into contact with the side surface of the semiconductor wafer W. The clamp electrodes 30a and 30b are formed of, for example, a conductive material such as copper, aluminum, or tungsten. Both of the clamp electrodes 30a and 30b may be movable in opposing directions (+X directions) to approach each other, or only one of the clamp electrodes 30a and 30b may be movable to approach the other one.

As the clamp electrodes 30a and 30b contact with the side surface of the semiconductor wafer W, the clamp electrodes 30a and 30b function as the rear electrode (for example, a drain electrode) connected to the substrate of the semiconductor wafer W. Accordingly, even when there is an insulating film on the rear surface of the semiconductor wafer W, the substrate of the semiconductor wafer W can be electrically connected to the measuring part 70 via the clamp electrodes 30a and 30b.

A thickness T30 of the clamp electrodes 30a and 30b in a direction (the Z direction) perpendicular to a support face of the stage 10 is smaller than a thickness Tw of the semiconductor wafer W. Accordingly, the clamp electrodes 30a and 30b are electrically connected only to the substrate of the semiconductor wafer W and are not electrically connected to semiconductor elements formed on a front surface region of the semiconductor wafer W. When the clamp electrodes 30a and 30b are connected to, for example, a drain electrode, the probe needle 21 may be connected to, for example, a source electrode or a gate electrode. Accordingly, the electrical characteristics of a semiconductor element can be measured by application of a voltage between the probe needle 21 and the clamp electrodes 30a and 30b. As long as the clamp electrodes 30a and 30b are not short-circuited with the semiconductor elements, the thickness T30 of the clamp electrodes 30a and 30b may be equal to or larger than the thickness Tw of the semiconductor wafer W.

The stage driver 40 moves or rotates the stage 10 under control of the controller 60.

The clamp driver 50 moves the clamp electrodes 30a and 30b in an X-Y plane on the stage 10 under control of the controller 60. Accordingly, the clamp electrodes 30a and 30b clamp the semiconductor wafer W from both sides and can be electrically connected to the semiconductor wafer W.

The probe card driver 52 moves the probe card 20 above the semiconductor wafer W on the stage 10 and brings the probe needle 21 into contact with a semiconductor element. The probe card 20 brings the probe needle 21 into contact with a semiconductor element E of the semiconductor wafer W from above the stage 10.

The transfer arm driver 54 moves the transfer arm 80. The transfer arm 80 transfers the semiconductor wafer W from outside and places the semiconductor wafer W on the stage 10.

The controller 60 controls the stage driver 40, the clamp driver 50, the probe card driver 52, and the transfer arm driver 54.

The measuring part 70 is electrically connected to the probe card 20 and the clamp electrodes 30a and 30b and applies power between the probe needle 21 and the clamp electrodes 30a and 30b. Further, the measuring part 70 measures electrical characteristics of a semiconductor element of the semiconductor wafer W acquired via the probe card 20 and the clamp electrodes 30a and 30b.

The controller 60 and the measuring part 70 may be constituted of, for example, one mutual computer or a plurality of separate computers.

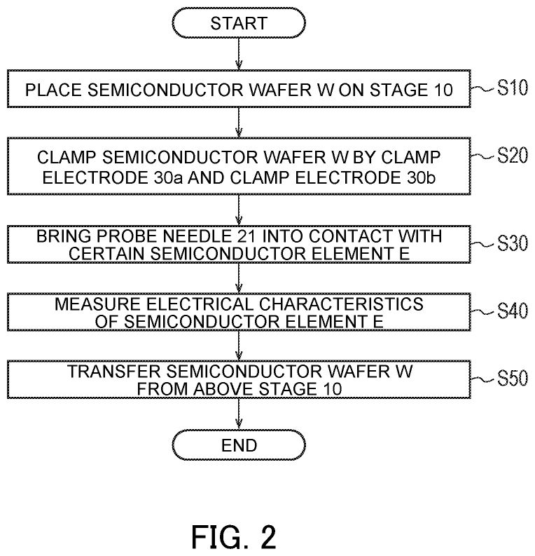

FIG. 2 is a flowchart illustrating an operation example of the probing device according to the first embodiment.

First, the transfer arm 80 transfers a semiconductor wafer W and places the semiconductor wafer W on the stage 10 (S10).

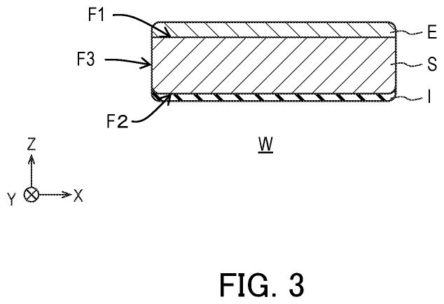

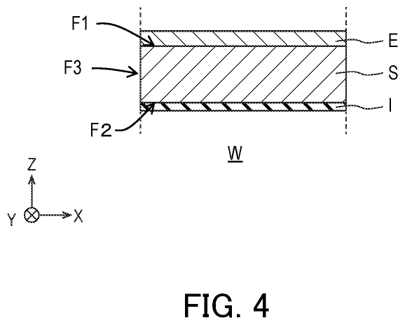

FIGS. 3 and 4 are sectional views illustrating a configuration example of the semiconductor wafer W placed on the stage 10. The semiconductor wafer W includes a substrate S, semiconductor elements E, and a rear insulating film I. The substrate S has a front surface F1, a rear surface F2 on the opposite side to the front surface F1, and a side surface F3 between the front surface F1 and the rear surface F2.

The substrate S is formed of, for example, a semiconductor material such as silicon, GaAs, or SiC.

The semiconductor elements E are provided on the front surface F1 of the substrate S. The semiconductor elements E are, for example, power semiconductor elements provided on an epitaxial layer.

The rear insulating film I is provided on the rear surface F2 of the substrate S. The rear insulating film I is a film formed on the rear surface F2 at the time of forming the semiconductor elements E on the front surface F1 and is removed in a subsequent backgrinding process. The rear insulating film I is hardly formed on the side surface F3 while being formed on the rear surface F2. The rear insulating film I is formed of, for example, an insulating material such as a silicon oxide film.

The semiconductor wafer W may be subjected to bevel grinding as illustrated in FIG. 3 or may be without bevel grinding as illustrated in FIG. 4.

Next, the clamp driver 50 moves the clamp electrodes 30a and 30b, and the semiconductor wafer W is clamped by the clamp electrode 30a and the clamp electrode 30b on the side surface F3 as illustrated in FIG. 1 (S20). Accordingly, the clamp electrodes 30a and 30b are in direct contact with the side surface F3 of the semiconductor wafer W and are electrically connected to the substrate S. The clamp electrodes 30a and 30b also have a function to fix the semiconductor wafer W in the X-Y plane.

Next, the probe card driver 52 moves the probe card 20 above the semiconductor wafer W and brings the probe needle 21 into contact with a certain semiconductor element E on the front surface F1 of the semiconductor wafer W (S30). With this process, the probe needle 21 is electrically connected to the semiconductor element E.

Next, the measuring part 70 applies power between the probe needle 21 and the clamp electrodes 30a and 30b. Accordingly, a voltage is applied to the semiconductor element E and the substrate S. The measuring part 70 measures various electrical characteristics of the semiconductor element E (S40). At this time, even when the substrate S is electrically insulated from the stage 10 by the rear insulating film I, the clamp electrodes 30a and 30b are electrically connected to the substrate S on the side surface F3. Therefore, the measuring part 70 can acquire the electrical characteristics of the semiconductor element E via the clamp electrodes 30a and 30b.

Subsequently, the transfer arm 80 transfers the semiconductor wafer W from above the stage 10 (S50), and a series of measuring processing ends.

As described above, the probing device 1 according to the present embodiment includes the clamp electrodes 30a and 30b which are configured to be movable in the X-Y plane on the stage 10 from the outer sides of the stage 10 to the center. With this configuration, the clamp electrodes 30a and 30b can be brought into contact with the side surface F3 of the semiconductor wafer W on the stage 10 and function as electrodes to be electrically connected to the substrate S. Therefore, even when the rear insulating film I covers the rear surface F2 of the semiconductor wafer W, the clamp electrodes 30a and 30b exert substantially the same functions as the rear electrode of the semiconductor wafer W, and the semiconductor elements E on the side of the front surface F1 of the semiconductor wafer W can be tested. The clamp electrodes 30a and 30b also function to fix the semiconductor wafer W at a predetermined position on the stage 10.

In the probing device 1 according to the present embodiment, the rear insulating film I covers the rear surface F2 of the semiconductor wafer W. The rear insulating film I is the same material as the silicon oxide film that covers the semiconductor elements E on the side of the front surface F1. This suppresses warp of the semiconductor wafer W and enables the semiconductor wafer W to be easily transferred to a subsequent process.

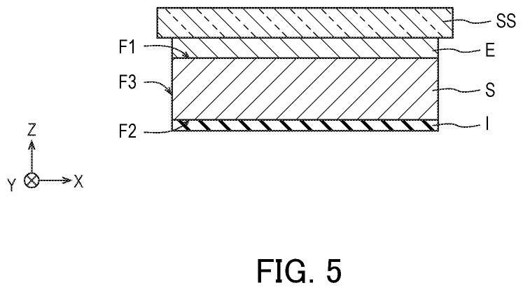

After the testing process of the semiconductor wafer W in the probing device 1 is performed, processes illustrated in FIGS. 5 to 12 are performed and then the semiconductor wafer W is singulated into semiconductor chips CH.

FIGS. 5 to 9 are sectional views illustrating a manufacturing process of a semiconductor device after the testing process of the semiconductor wafer W is performed.

After the testing process of the semiconductor wafer W is performed, as illustrated in FIG. 5, a support substrate SS is attached on the front surface F1 of the semiconductor wafer W. The support substrate SS is, for example, a glass substrate and is attached onto the silicon oxide film covering the semiconductor elements E with an adhesive. At this time, there is also the rear insulating film I formed on the rear surface F2. Therefore, the semiconductor wafer W hardly warps and transferring or attaching of the support substrate SS is easy.

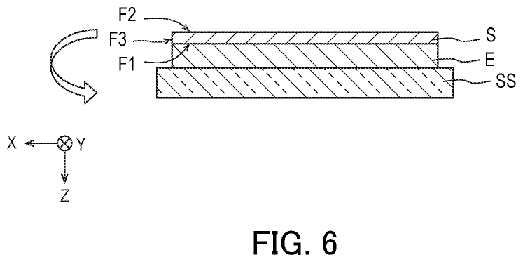

Next, the semiconductor wafer W is inverted as illustrated in FIG. 6. Next, the rear insulating film I and the substrate S are polished from the side of the rear surface F2 using a CMP (Chemical Mechanical Polishing) method or an etching method. With this process, the rear insulating film I is removed and the substrate S is thinned.

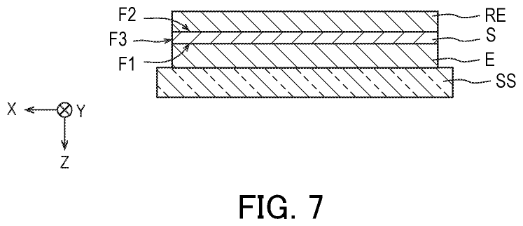

Next, the material of a rear electrode RE is deposited on the rear surface F2 of the semiconductor wafer W using a sputtering method or the like as illustrated in FIG. 7. The rear electrode RE is formed of, for example, a low-resistance metallic material such as gold, copper, or aluminum.

Next, a dicing tape DT is attached on the side of the rear surface F2 of the semiconductor wafer W. The dicing tape DT is formed of, for example, flexible resin and is attached onto the rear electrode RE.

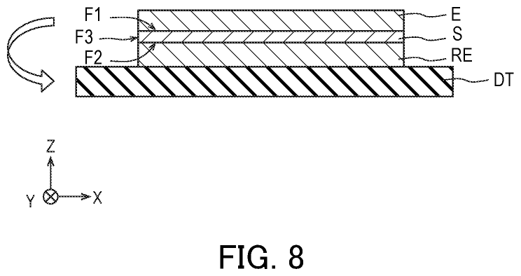

Next, the semiconductor wafer W is inverted again as illustrated in FIG. 8. Next, the support substrate SS is detached from the semiconductor wafer W.

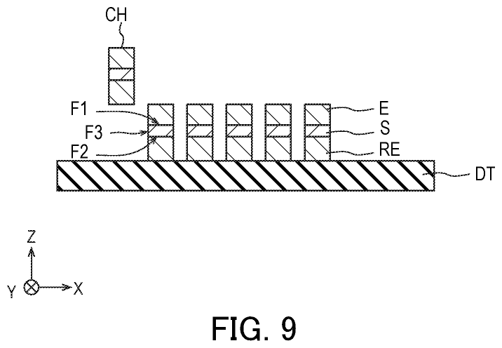

Next, the semiconductor wafer W is singulated into a plurality of semiconductor chips CH using a dicing blade or a laser as illustrated in FIG. 9. The semiconductor chips CH are picked up by another device and are packaged in an assembling process.

### Second Embodiment

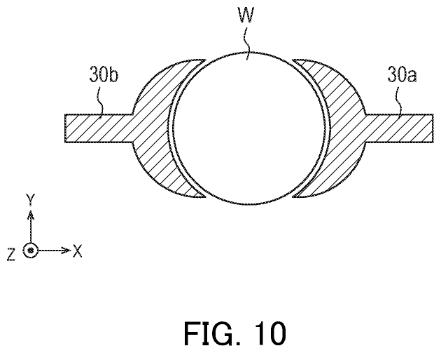

FIG. 10 is a plan view illustrating a configuration example of clamp electrodes according to a second embodiment. As viewed from the Z direction, clamp electrodes 30a and 30b are arranged on both sides (+X directions) of a semiconductor wafer W. At the time of clamping of the semiconductor wafer W, the clamp electrode 30a located in the +X direction of the semiconductor wafer W moves in the −X direction and the clamp electrode 30b located in the −X direction of the semiconductor wafer W moves in the +X direction.

The clamp electrodes 30a and 30b respectively have a shape following the outer shape of the semiconductor wafer W on a contact face with the semiconductor wafer W. For example, the clamp electrodes 30a and 30b respectively have a substantially arc shape which is same as the outer shape of the semiconductor wafer W on the contact face with the semiconductor wafer W. With this configuration, the clamp electrodes 30a and 30b can sandwich and fix the semiconductor wafer W therebetween and connect to the substrate S in a large area. This can decrease the contact resistance between the clamp electrodes 30a and 30b and the substrate S.

At the time of clamping the semiconductor wafer W, the clamp electrodes 30a and 30b both may move to clamp the semiconductor wafer W. It is also possible that one of the clamp electrodes 30a and 30b is fixed at a predetermined position and that the other one moves toward the fixed one to clamp the semiconductor wafer W. In this case, the semiconductor wafer W moves slightly sliding on the stage 10. However, this is acceptable in measuring the electrical characteristics of the semiconductor elements.

### Third Embodiment

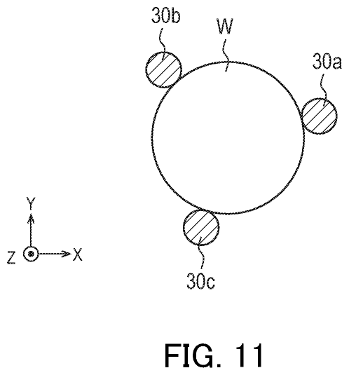

FIG. 11 is a plan view illustrating a configuration example of clamp electrodes according to a third embodiment. Clamp electrodes 30a, 30b, and 30c each have a pin shape. In a cross section parallel to the X-Y plane, the clamp electrodes 30a, 30b, and 30c may respectively have a shape such as a cylindrical shape, an elliptic columnar shape, or a polygonal columnar shape. As viewed from the Z direction, the clamp electrodes 30a, 30b, and 30c are arranged evenly in three directions of the semiconductor wafer W and sandwich the semiconductor wafer W from the three directions. At the time of clamping the semiconductor wafer W, the clamp electrodes 30a, 30b, and 30c move toward the semiconductor wafer W and clamp the semiconductor wafer W.

Since the clamp electrodes 30a, 30b, and 30c each have a pin shape and clamp the semiconductor wafer W from three directions, the semiconductor wafer W having various sizes or shapes can be clamped.

At the time of clamping the semiconductor wafer W, all the clamp electrodes 30a, 30b, and 30c may move to clamp the semiconductor wafer W. Besides, it is also possible that at least one of the clamp electrodes 30a, 30b, and 30c is fixed at a predetermined position and that the remaining clamp electrodes move to clamp the semiconductor wafer W. While the semiconductor wafer W moves slightly sliding on the stage 10 in this case, this does not cause any problem in measuring the electrical characteristics of the semiconductor elements.

Further, the number of the clamp electrodes may be four or more. Even in this case, it is preferable that the clamp electrodes are arranged evenly around the semiconductor wafer W.

### Fourth Embodiment

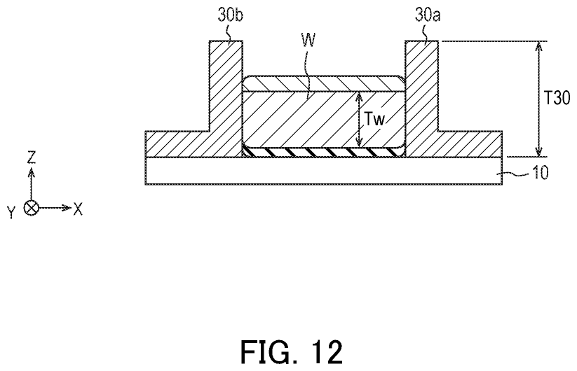

FIG. 12 is a sectional view illustrating a configuration example of clamp electrodes according to a fourth embodiment. The thickness T30 of the clamp electrodes 30a and 30b in the Z direction is larger than the thickness of the semiconductor wafer W or the thickness Tw of the substrate S. Therefore, the clamp electrodes 30a and 30b can be in contact with the whole of the side surface of the semiconductor wafer W (the side surface of the substrate S) in the Z direction and the contact face between the clamp electrodes 30a and 30b and the semiconductor wafer W can be enlarged. Accordingly, the clamp electrodes 30a and 30b can be in contact with the substrate S with a low resistance. Other configurations of the fourth embodiment may be identical to those of the first embodiment. Accordingly, the fourth embodiment can attain identical effects as those of the first embodiment.

The clamp electrodes 30a and 30b according to the fourth embodiment may be applied to any of the clamp electrodes 30a and 30b according to the second embodiment or the clamp electrodes 30a to 30c according to the third embodiment. Accordingly, the fourth embodiment can also attain identical effects as those of the second or third embodiment.

### Fifth Embodiment

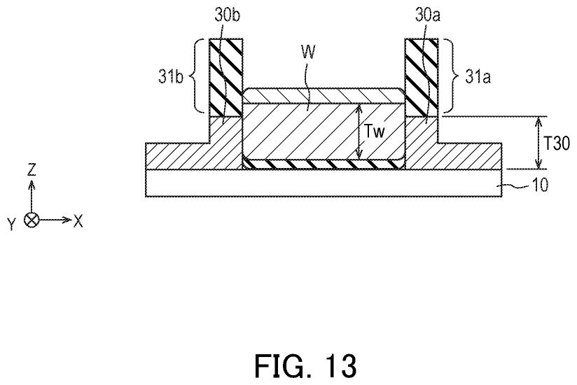

FIG. 13 is a sectional view illustrating a configuration example of clamp electrodes according to a fifth embodiment. When the clamp electrodes 30a and 30b are in contact with the entire side surface of the semiconductor wafer W in the Z direction, there is a possibility that the clamp electrodes 30a and 30b are short-circuited with the semiconductor elements on the front surface F1.

Therefore, in the fifth embodiment, the thickness T30 of the clamp electrodes 30a and 30b in the Z direction is smaller than the thickness of the semiconductor wafer W or the thickness Tw of the substrate S.

Insulating layers 31a and 31b are provided on the clamp electrodes 30a and 30b, respectively. The insulating layers 31a and 31b are formed of, for example, a non-conductive material such as ceramics or resin.

In the Z direction, the thickness T30 of the clamp electrodes 30a and 30b is smaller than the thickness of the semiconductor wafer W or the thickness Tw of the substrate S. Therefore, the clamp electrode 30a and 30b can be prevented from being short-circuited with the semiconductor elements on the side of the front surface F1. Other configurations of the fifth embodiment may be identical to those of the first embodiment. Accordingly, the fifth embodiment can attain identical effects as those of the first embodiment.

Further, the clamp electrodes 30a and 30b according to the fifth embodiment may be applied to any of the clamp electrodes 30a and 30b according to the second embodiment or the clamp electrodes 30a to 30c according to the third embodiment. Accordingly, the fifth embodiment can also attain identical effects as those of the second or third embodiment.

While the clamp electrodes 30a and 30b respectively have an L-shape in a cross section cut along a Z-X plane in FIGS. 12 and 13, the shape of the clamp electrodes 30a and 30b is not limited thereto.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus comprising:
a stage configured to support a semiconductor wafer;
a probe card positioned above the stage; and
a first electrode formed of a conductive material, being movable on the stage from an outer side of the stage toward a center thereof, and being contactable with a side surface of the semiconductor wafer.

2. The apparatus of claim 1, wherein
the probe card brings a probe into contact with the semiconductor wafer from above the stage, and
the apparatus further comprises a measuring part configured to apply power between the probe and the first electrode and to measure electrical characteristics of the semiconductor wafer.

3. The apparatus of claim 1, wherein a thickness of the first electrode in a perpendicular direction to a support face of the stage on which the semiconductor wafer is placed is smaller than a thickness of the semiconductor wafer.

4. The apparatus of claim 2, wherein a thickness of the first electrode in a perpendicular direction to a support face of the stage on which the semiconductor wafer is placed is smaller than a thickness of the semiconductor wafer.

5. The apparatus of claim 1, wherein the first electrode has a shape following an outer shape of the semiconductor wafer on a contact face with the semiconductor wafer as viewed from a perpendicular direction to a support face of the stage.

6. The apparatus of claim 2, wherein the first electrode has a shape following an outer shape of the semiconductor wafer on a contact face with the semiconductor wafer as viewed from a perpendicular direction to a support face of the stage.

7. The apparatus of claim 5, wherein the contact face of the first electrode has a substantially arc shape as viewed from the perpendicular direction.

8. The apparatus of claim 1, further comprising a second electrode configured to sandwich the semiconductor wafer with the first electrode as viewed from a perpendicular direction to a support face of the stage on which the semiconductor wafer is placed.

9. The apparatus of claim 8, wherein thicknesses of the first and second electrodes in the perpendicular direction are smaller than a thickness of the semiconductor wafer.

10. The apparatus of claim 1, further comprising an insulating layer formed of a non-conductive material and provided on the first electrode.

11. The apparatus of claim 1, further comprising a second electrode and a third electrode configured to sandwich the semiconductor wafer with the first electrode from three directions as viewed from a perpendicular direction to a support face of the stage on which the semiconductor wafer is placed, wherein
the first to third electrodes each have a pin shape.

12. The apparatus of claim 11, wherein thicknesses of the first to third electrodes in a perpendicular direction to a support face of the stage supporting the semiconductor wafer are smaller than a thickness of the semiconductor wafer.

13. The apparatus of claim 8, wherein thicknesses of the first and second electrodes in the perpendicular direction are larger than a thickness of the semiconductor wafer.

14. The apparatus of claim 1, wherein the stage is electrically insulated from the semiconductor wafer.
